(19) United States
(12) Patent Application Publication
(10) Pub. No.: US 2025/0007247 A1
(43) Pub. Date: Jan. 2, 2025

(54) VERTICAL CAVITY SURFACE EMITTING LASER DEVICE WITH DUAL WAVELENGTH BANDS

(71) Applicant: Lumentum Operations LLC, San Jose, CA (US)

(72) Inventors: Yeyu ZHU, San Jose, CA (US); Jun YANG, Cupertino, CA (US)

(21) Appl. No.: 18/478,677

(22) Filed: Sep. 29, 2023

Related U.S. Application Data
(60) Provisional application No. 63/510,517, filed on Jun. 27, 2023.

(51) Int. Cl. H01S 5/183; H01S 5/042; H01S 5/22; H01S 5/30

(52) U.S. Cl. CPC H01S 5/18397; H01S 5/04252; H01S 5/04256; H01S 5/18377; H01S 5/2228; H01S 5/3095

(57) ABSTRACT

A dual-emission-wavelength vertical-cavity surface-emitting laser (VCSEL) device includes a substrate layer; a first distributed Bragg reflector (DBR) arranged on the substrate layer and being based on a first wavelength, a second DBR arranged on the first DBR and being based on a second wavelength that is different from the first wavelength, a third DBR arranged on the second DBR and being based on a third wavelength that is different from the first and the second wavelengths; a first active layer configured to generate a first laser light at a first emission wavelength and being arranged between the first DBR and the second DBR; and a second active layer configured to generate a second laser light at a second emission wavelength that is different from the first emission wavelength and being arranged between the second DBR and the third DBR.

### CROSS-REFERENCE TO RELATED APPLICATION

This Patent Application claims priority to U.S. Patent Application No. 63/510,517, filed on Jun. 27, 2023. The disclosure of the prior Application is considered part of and is incorporated by reference into this Patent Application.

### TECHNICAL FIELD

The present disclosure relates generally to vertical-cavity surface-emitting laser (VCSEL) devices with dual wavelength bands.

### BACKGROUND

A VCSEL is a type of semiconductor laser diode (e.g., a laser resonator) with laser beam emission perpendicular from a top surface or a bottom surface of the device. VCSELs typically includes two distributed Bragg reflector (DBR) mirrors arranged parallel to a wafer surface with an active region arranged between the two DBR mirrors. The active region includes one or more quantum wells for laser light generation. VCSELs are widely used in various applications, such as data communications, sensing, and optical interconnects, due to advantages over other types of lasers. For example, VCSELs typically have lower power consumption (e.g., VCSELs require much lower power to operate than other types of lasers, making them more energy-efficient and cost-effective), are capable of high-speed operation (e.g., making VCSELs ideal for data communications and other applications that require fast signal transmission), have narrow beam divergence (e.g., the narrow beam divergence of VCSELs allows for high coupling efficiency with optical fibers and other components, making VCSELs easier to integrate into optical systems), and have high reliability (e.g., VCSELs have a long operating lifetime and are less prone to failure than other types of lasers).

### SUMMARY

In some implementations, a VCSEL device includes a substrate layer; a first DBR arranged on the substrate layer, wherein the first DBR is configured with a first photonic stopband having a first frequency bandwidth, wherein the first DBR comprises a first plurality of alternately stacked high-index layers and low-index layers, and wherein each high-index layer and each low-index layer of the first plurality of alternately stacked high-index layers and low-index layers has a respective first optical thickness based on a first wavelength; a second DBR arranged on the first DBR, wherein the second DBR is configured with a second photonic stopband having a second frequency bandwidth that partially, but not fully, overlaps with the first frequency bandwidth, wherein the second DBR comprises a second plurality of alternately stacked high-index layers and low-index layers, and wherein each high-index layer and each low-index layer of the second plurality of alternately stacked high-index layers and low-index layers has a respective second optical thickness based on a second wavelength that is different from the first wavelength; an active layer comprising one or more quantum wells and configured to generate a laser light at an emission wavelength, wherein the active layer is arranged between the first DBR and the second DBR; and an optical output arranged over the second DBR, wherein the laser light is emitted from the VCSEL device via the optical output.

In some implementations, a dual-emission-wavelength VCSEL device includes a substrate layer; a first DBR arranged on the substrate layer, wherein the first DBR is configured with a first photonic stopband having a first frequency bandwidth, wherein the first DBR comprises a first plurality of alternately stacked high-index layers and low-index layers, and wherein each high-index layer and each low-index layer of the first plurality of alternately stacked high-index layers and low-index layers has a respective first optical thickness based on a first wavelength; a second DBR arranged on the first DBR, wherein the second DBR is configured with a second photonic stopband having a second frequency bandwidth that partially, but not fully, overlaps with the first frequency bandwidth, wherein the second DBR comprises a second plurality of alternately stacked high-index layers and low-index layers, and wherein each high-index layer and each low-index layer of the second plurality of alternately stacked high-index layers and low-index layers has a respective second optical thickness based on a second wavelength that is different from the first wavelength; a third DBR arranged on the second DBR, wherein the third DBR is configured with a third photonic stopband having a third frequency bandwidth that partially, but not fully, overlaps with the first frequency bandwidth and the second frequency bandwidth, wherein the third DBR comprises a third plurality of alternately stacked high-index layers and low-index layers, and wherein each high-index layer and each low-index layer of the third plurality of alternately stacked high-index layers and low-index layers has a respective third optical thickness based on a third wavelength that is different from the first wavelength and the second wavelength, a first active layer comprising one or more first quantum wells and configured to generate a first laser light at a first emission wavelength, wherein the first active layer is arranged between the first DBR and the second DBR; a second active layer comprising one or more second quantum wells and configured to generate a second laser light at a second emission wavelength that is different from the first emission wavelength, wherein the second active layer is arranged between the second DBR and the third DBR; a first optical output arranged over the second DBR, wherein the first laser light is emitted from the dual-emission-wavelength VCSEL device via the first optical output; and a second optical output arranged over the third DBR, wherein the second laser light is emitted from the dual-emission-wavelength VCSEL device via the second optical output.

In some implementations, a dual-emission-wavelength VCSEL device includes a substrate layer; a first DBR arranged on the substrate layer, wherein the first DBR comprises a first plurality of alternately stacked high-index layers and low-index layers, and wherein each high-index layer and each low-index layer of the first plurality of alternately stacked high-index layers and low-index layers has a respective first optical thickness based on a reflection wavelength; a second DBR arranged on the first DBR, wherein the second DBR comprises a second plurality of alternately stacked high-index layers and low-index layers, and wherein each high-index layer and each low-index layer of the second plurality of alternately stacked high-index layers and low-index layers has a respective second optical thickness based on the reflection wavelength; a third DBR arranged on the second DBR, wherein the third DBR comprises a third plurality of alternately stacked high-index layers and low-index layers, and wherein each high-index layer and each low-index layer of the third plurality of alternately stacked high-index layers and low-index layers has a respective third optical thickness based on the reflection wavelength; a first active layer comprising one or more first quantum wells and configured to generate a first laser light at a first emission wavelength, wherein the first active layer is arranged between the first DBR and the second DBR; a second active layer comprising one or more second quantum wells and configured to generate a second laser light at a second emission wavelength that is different from the first emission wavelength, wherein the second active layer is arranged between the second DBR and the third DBR; a first optical output arranged over the second DBR, wherein the first laser light is emitted from the dual-emission-wavelength VCSEL device via the first optical output; and a second optical output arranged over the third DBR, wherein the second laser light is emitted from the dual-emission-wavelength VCSEL device via the second optical output.

### BRIEF DESCRIPTION OF THE DRAWINGS

FIGS. 1A and 1B are diagrams depicting a top-view of an example emitter and a cross-sectional view of example emitter along the line X-X, respectively.

FIG. 2 is a diagram depicting a cross-section of a VCSEL structure according to one or more implementations.

FIG. 3 is a diagram of three reflectance spectrums for three different DBRs that are based on different wavelengths, respectively.

FIG. 4 is a diagram depicting a cross-section of a VCSEL structure according to one or more implementations.

FIG. 5 is a diagram depicting a cross-section of a VCSEL structure according to one or more implementations.

FIG. 6 is a diagram depicting a cross-section of a VCSEL structure according to one or more implementations.

FIG. 7A shows a VCSEL chip configured for dual-wavelength band emission according to one or more implementations.

FIG. 7B shows a VCSEL chip configured for dual-wavelength band emission according to one or more implementations.

### DETAILED DESCRIPTION

The following detailed description of example implementations refers to the accompanying drawings. The same reference numbers in different drawings may identify the same or similar elements.

Different applications, such as three-dimensional sensing and data communications, may use semiconductor lasers emitting at different wavelength bands. For example, short-range communications may use VCSELs emitting at around 850 nm, whereas long-range communications may use VCSELs emitting above 1.3 μm or even above 1.5 μm. Three-dimensional sensing applications, such as light detection and ranging (LiDAR), may use VCSELs emitting at different wavelengths such as 905 nm and 940 nm to enable varied functions.

VCSELs emitting at different wavelength bands require different active regions (InGaAs for 850 nm, GaInNAs(Sb) for greater than 1.3 μm) and different mirror pair designs. Thus, a VCSEL typically can only focus on one wavelength band. As a result, separate laser chips are used for applications that require multiple wavelength bands, which increases the size and the cost of the laser module and may increase power consumption of the laser module due to the need to operate separate laser chips. In particular, separated VCSEL chips with different epitaxial (epi) structures are typically used for applications requiring different lasing wavelengths. The multiple VCSEL chips increase the module size and cost.

A typical VCSEL has a sandwich structure mainly consisting of top distributed Bragg reflector (DBR), a bottom DBR, and an active region (e.g., an active layer) arranged between the top DBR and the bottom DBR. Each DBR is made of multiple alternatively stacked high-index layers and low-index layers, and each layer has an optical thickness of odd integer of ¼-Lambda (¼, ¾, . . . ). The optical thickness of one lambda is the length of one wavelength divided by the refractive index. Thus, all three parts of the typical VCSEL, including the top DBR, the active region, and the bottom DBR are typically based on the same wavelength.

A VCSEL structure is provided that enables operation at separate wavelength regimes (e.g., two or more separate wavelengths or wavelength bands) in a same, single chip. Thus, the VCSEL structure is capable of emitting lasers at different wavelengths. For example, the VCSEL structure may be configured to emit a first laser light at a first wavelength and a second laser light at a second wavelength that is different from the first wavelength. As a result, the VCSEL structure may provide a compact VCSEL device capable of dual wavelength emission that may reduce a size, a power consumption, and a manufacturing cost relative to laser modules that require two separate laser chips to implement separate wavelength regimes.

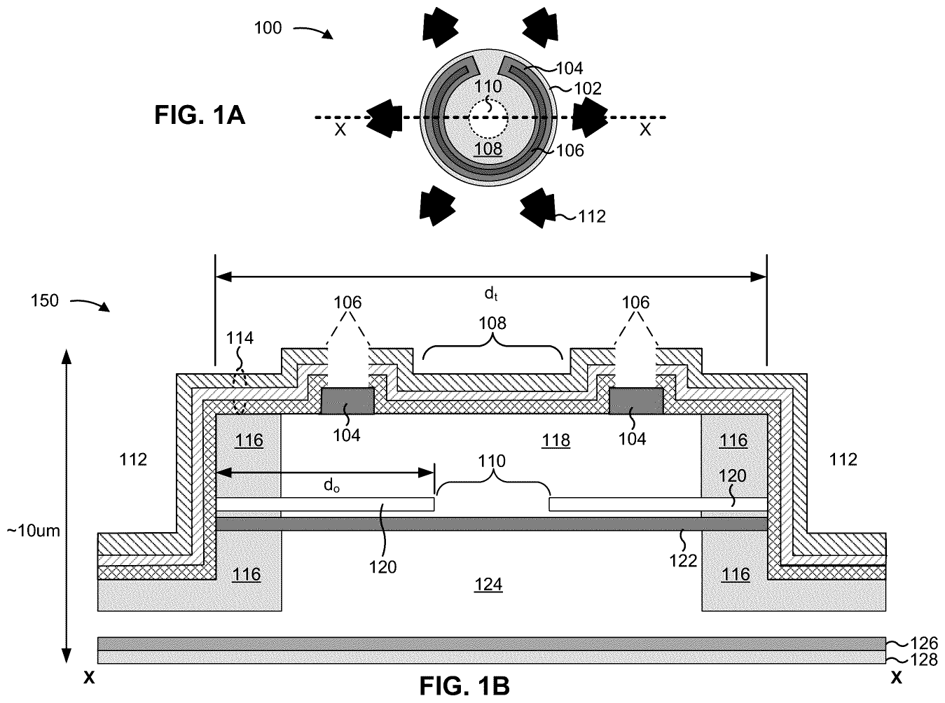

FIGS. 1A and 1B are diagrams depicting a top-view of an example emitter 100 and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g. a dielectric layer or a passivation layer) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium grey area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical output 108 in a portion of emitter 100 within the inner radius of the partial ring-shape of ohmic metal layer 104. In some implementations, the optical output 108 may be an optical aperture configured to permit light to exit the emitter 100. The emitter 100 emits a laser beam via optical output 108. As further shown, emitter 100 also includes a current confinement aperture 110 (e.g., an oxide aperture formed by an oxidation layer of emitter 100 (not shown)). Current confinement aperture 110 is formed below optical output 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical output 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dₜ. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g. a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al203layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO2 layer, a Si3N4 layer, an Al203 layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical output 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bond pad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

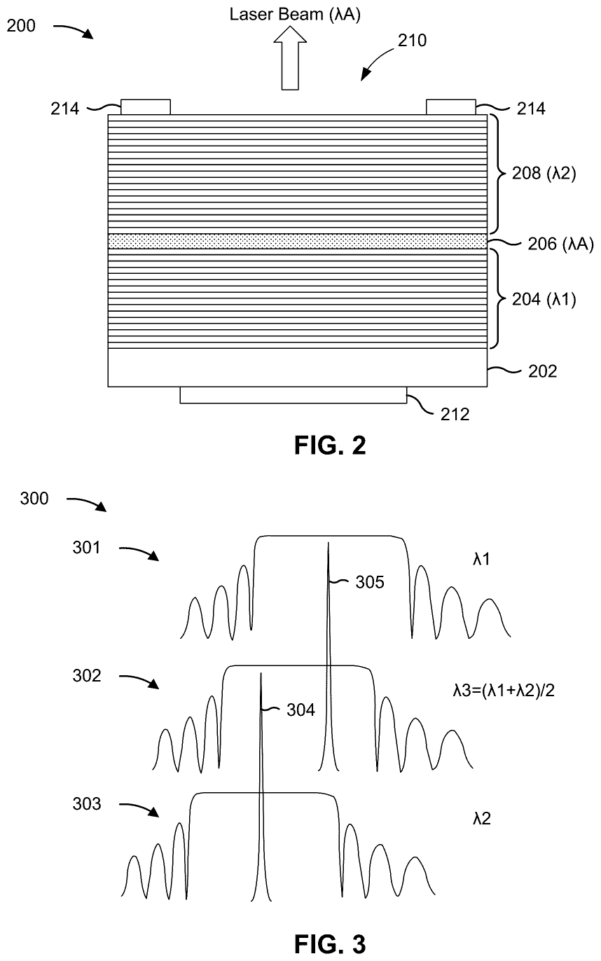

FIG. 2 is a diagram depicting a cross-section of a VCSEL structure 200 according to one or more implementations. The VCSEL structure 200 may be integrated on a single laser chip to form a VCSEL device. The VCSEL structure 200 may include a substrate layer 202, a first DBR 204 (e.g., a bottom DBR), an active layer 206 (e.g., an active region), a second DBR 208 (e.g., a top DBR), and an optical output 210. The VCSEL structure 200 may also include an oxidation layer and a current confinement aperture (not explicitly illustrated). Thus, some aspects of the VCSEL structure 200 may not be shown for the sake of simplifying the illustration of the VCSEL structure 200.

The first DBR 204 may be arranged on the substrate layer 202. The first DBR 204 is configured with a first photonic stopband having a first frequency bandwidth. The first DBR 204 may include a first plurality of alternately stacked high-index layers and low-index layers, where each high-index layer and each low-index layer of the first plurality of alternately stacked high-index layers and low-index layers has a respective first optical thickness based on a first wavelength 21. Thus, a structure of the first DBR 204 is based on the first wavelength 21, which may also be referred to as a first reflection wavelength.

The second DBR 208 may be arranged on the first DBR 204. The second DBR 208 may be configured with a second photonic stopband having a second frequency bandwidth that partially, but not fully, overlaps with the first frequency bandwidth of the first DBR 204. The second DBR 208 may include a second plurality of alternately stacked high-index layers and low-index layers, where each high-index layer and each low-index layer of the second plurality of alternately stacked high-index layers and low-index layers has a respective second optical thickness based on a second wavelength μ2 that is different from the first wavelength λ1. Thus, a structure of the second DBR 208 is based on the second wavelength λ2, which may also be referred to as a second reflection wavelength that is different form the first reflection wavelength. For example, the first photonic stopband may have a first center frequency and the second photonic stopband has a second center frequency offset from the first center frequency. As a result, the first wavelength λ1 and the second wavelength λ2 are different.

The active layer 206 may be arranged between the first DBR 204 and the second DBR 208. For example, the active layer 206 may be arranged on top of the first DBR 204 and below the second DBR 208. The active layer 206 may include one or more quantum wells and may be configured to generate a laser light at an emission wavelength λA. For example, the active layer 206 may have a gain profile (e.g., based on a doping) and a layer thickness configured for emitting the laser light at the emission wavelength λA. The emission wavelength λA may be located in an overlapped portion of the first photonic stopband and the second photonic stopband. In some implementations, the emission wavelength λA may be equal to or substantially equal to the first wavelength λ1, may be equal to or substantially equal to the second wavelength λ2, or may be equal to a wavelength between the first wavelength λ1 and the second wavelength λ2, such as an average of the first wavelength λ1 and the second wavelength λ2.

The optical output 210 may be arranged over the second DBR 208. The laser light may be emitted from the VCSEL device via the optical output 210.

The VCSEL structure 200 may further include a bottom ohmic contact 212 (e.g., a bottom electrical contact) arranged on a backside of the substrate layer 202 and a top ohmic contact 214 (e.g., a top electrical contact) arranged on the second DBR 208. The bottom ohmic contact 212 and the top ohmic contact 214 may be configured to cause an electric current to flow between the bottom ohmic contact 212 and the top ohmic contact 214 for producing the laser light at the active layer 206.

For a VCSEL with an emission wavelength around 1 micron, a typical DBR provides a stop-band width of about 100 nm (or more or less). Thus, to maintain a reasonable high reflection for different wavelengths, for example, dual wavelengths λ1 and λ2, within a similar optical stopband or within overlapped optical stopbands, a difference between the first wavelength λ1 and the second wavelength λ2 should be less than 100 nm (or more or less) in a wavelength range of 1 micron. In other words, the difference between the first wavelength λ1 and the second wavelength λ2 should be less than a stop-band width of the first DBR 204 and/or the second DBR 208.

As indicated above, FIG. 2 is provided as an example. Other examples may differ from what is described with regard to FIG. 2.

FIG. 3 is a diagram 300 of three reflectance spectrums 301-303 for three different DBRs that are based on different wavelengths, respectively. The diagram 300 also show two different longitudinal modes 304 and 305 at the first wavelength λ1 and the second wavelength λ2, respectively, that correspond to a respective resonator cavity formed by a respective pair of DBRs. For example, the first wavelength may be 940 nm and the second wavelength λ2 may be 905 nm. The reflectance spectrum 301 corresponds to a first DBR that is based on the first wavelength λ1. The reflectance spectrum 302 corresponds to a second DBR that is based on an average wavelength (λ1+λ2)/2 of the first wavelength λ1 and the second wavelength λ2. Thus, the second DBR is based on a third wavelength λ3. The reflectance spectrum 303 corresponds to a third DBR that is based on the second wavelength λ2.

The three DBRs may have similar or overlapped stopbands. For example, the reflectance spectrum 301 has a first photonic stopband that has a first center frequency, the reflectance spectrum 302 has a second photonic stopband that has a second center frequency that may be offset from the first center frequency, and the reflectance spectrum 303 has a third photonic stopband that has a third center frequency that may be offset from the first center frequency and the second center frequency.

As indicated above, FIG. 3 is provided as an example. Other examples may differ from what is described with regard to FIG. 3.

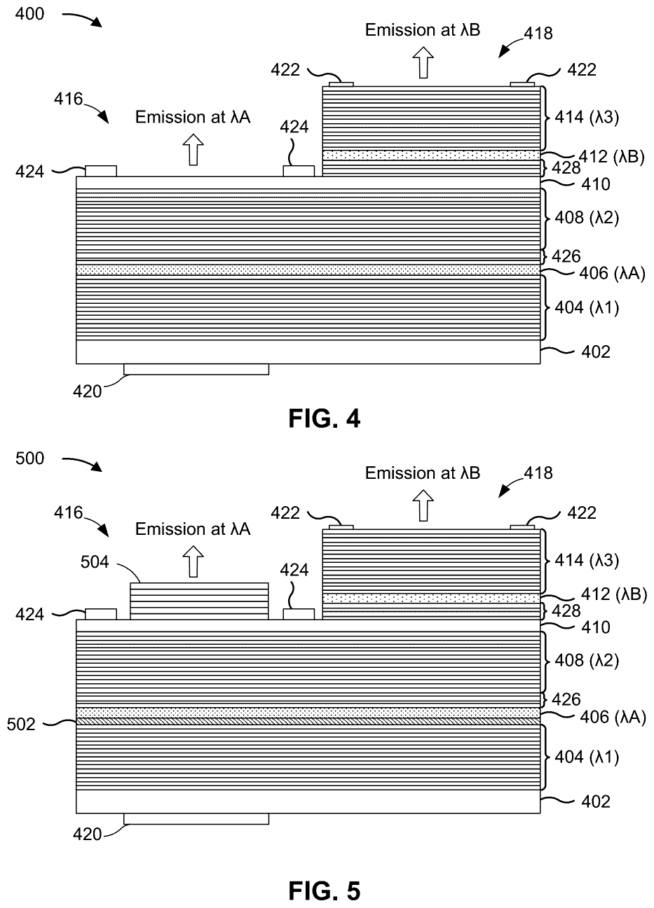

FIG. 4 is a diagram depicting a cross-section of a VCSEL structure 400 according to one or more implementations. The VCSEL structure 400 may be part of a chip-level integrated dual-emission-wavelength emitter (e.g., a dual-emission-wavelength VCSEL device) integrated on a single laser chip. The VCSEL structure 400 is configured with two separate wavelength regimes (e.g., dual-emission-wavelength regimes). In other words, the VCSEL structure 400 may be configured to generate laser beams at two different emission wavelengths.

The VCSEL structure 400 may include a substrate layer 402, a first DBR 404 (e.g., a bottom DBR), a first active layer 406 (e.g., first active region), a second DBR 408 (e.g., a middle DBR), a contact buffer 410, a second active layer 412 (e.g., a second active region), a third DBR 414 (e.g., a top DBR), a first optical output 416, a second optical output 418, a bottom ohmic contact 420 (e.g., a bottom electrical contact), a top ohmic contact 422 (e.g., a top electrical contact), a middle ohmic contact 424 (e.g., a middle electrical contact), an optional fourth DBR 426, and an optional fifth DBR 428. The VCSEL structure 400 may also include an oxidation layer and a current confinement aperture (not explicitly illustrated). Thus, some aspects of the VCSEL structure 400 may not be shown for the sake of simplifying the illustration of the VCSEL structure 400.

The first DBR 404 may be arranged on the substrate layer 402. The first DBR 404 may be configured with a first photonic stopband having a first frequency bandwidth. The first DBR 404 may include a first plurality of alternately stacked high-index layers and low-index layers, where each high-index layer and each low-index layer of the first plurality of alternately stacked high-index layers and low-index layers has a respective first optical thickness based on a first wavelength λ1.

The second DBR 408 may be arranged on the first DBR 404. The second DBR 408 may be configured with a second photonic stopband having a second frequency bandwidth that partially, but not fully, overlaps with the first frequency bandwidth. The second DBR 408 may include a second plurality of alternately stacked high-index layers and low-index layers, where each high-index layer and each low-index layer of the second plurality of alternately stacked high-index layers and low-index layers has a respective second optical thickness based on a second wavelength λ2 that is different from the first wavelength λ1.

The third DBR 414 may be arranged on the second DBR 408. The third DBR 414 may be configured with a third photonic stopband having a third frequency bandwidth that partially, but not fully, overlaps with the second frequency bandwidth. The third frequency bandwidth may also partially, but not fully, overlap with the first frequency bandwidth. The third DBR 414 may include a third plurality of alternately stacked high-index layers and low-index layers, where each high-index layer and each low-index layer of the third plurality of alternately stacked high-index layers and low-index layers has a respective third optical thickness based on a third wavelength λ3 that is different from the first wavelength λ1 and the second wavelength λ2. The third DBR 414 may be a dielectric DBR and/or a semiconductor DBR. Alternatively, the third DBR 414 may include a dielectric DBR (e.g., one or more pairs of high-index layers and low-index layers are made out of a dielectric material). For example, to enable a thinner epitaxial thickness (e.g., less layer pairs) and/or require less etching for the middle ohmic contact, the third DBR 414 may be made (all or partially) of dielectric DBRs.

The first photonic stopband may have a first center frequency, the second photonic stopband may have a second center frequency offset from the first center frequency, and the third photonic stopband may have a third center frequency offset from the first center frequency and the second center frequency. For example, the first photonic stopband may correspond to the reflectance spectrum 301, the second photonic stopband may correspond to the reflectance spectrum 302, and the third photonic stopband may correspond to the reflectance spectrum 303 described in connection with FIG. 3.

The first active layer 406 may be arranged between the first DBR 404 and the second DBR 408, and may include one or more first quantum wells and configured to generate a first laser light at a first emission wavelength λA. For example, the first emission wavelength λA may be at or approximately at the first wavelength λ1. The first active layer 406 may have a first gain profile (e.g., corresponding to a first doping) and a first thickness configured for emitting the first laser light at the first emission wavelength λA. The second active layer 412 may be arranged between the second DBR 408 and the third DBR 414, and may include one or more second quantum wells and configured to generate a second laser light at a second emission wavelength λB that is different from the first emission wavelength λA. For example, the second emission wavelength λB may be at or approximately at the third wavelength λ3. The second active layer 412 may have a second gain profile (e.g., corresponding to a second doping) and a second thickness configured for emitting the second laser light at the second emission wavelength λB.

The second DBR 408 may be used as a top DBR for the first active layer 406 and may be used as a bottom DBR for the second active layer 412. Thus, the first DBR 404, the first active layer 406, and the second DBR 408 may form a first emission structure within the dual-emission-wavelength VCSEL device corresponding to a first resonator cavity, and the second DBR 408, the second active layer 412, and the third DBR may form a second emission structure within the dual-emission-wavelength VCSEL device corresponding to a second resonator cavity, the first DBR 404 may also be a part of the bottom DBR to provide some reflection to the second resonator cavity. The first emission structure may be configured to generating lasers at the first emission wavelength λA, and the second emission structure may be configured to generating lasers at the second emission wavelength λB. The first emission structure and the second emission structure share the second DBR 408 for dual-emission-wavelength emission.

In some implementations, to balance a reflection efficiency for both the first wavelength λ1 and the third wavelength λ3, the second wavelength λ2 may have a value between the first wavelength λ1 and the third wavelength λ3. For example, the second wavelength λ2 may be equal to an average wavelength (λ1+λ3)/2 of the first wavelength λ1 and the third wavelength λ3. Alternatively, in some implementations, the first wavelength λ1 may be between the second wavelength λ2 and the third wavelength λ3, or the third wavelength λ3 may be between the first wavelength λ1 and the second wavelength λ2.

The first optical output 416 may be arranged over the second DBR 408. The first laser light with the first emission wavelength λA may be emitted from the VCSEL structure 400 (e.g., from the dual-emission-wavelength VCSEL device) via (through) the first optical output. For example, a first current confinement aperture (not illustrated) corresponding to the first active layer 406 and the first laser light may be arranged under the first optical output 416. The second optical output 418 may be arranged over the third DBR 414. The second optical output 418 may be laterally offset from the first optical output 416. The second laser light with the second emission wavelength λB may be emitted from the VCSEL structure 400 (e.g., from the dual-emission-wavelength VCSEL device) via (through) the second optical output 418. For example, a second current confinement aperture (not illustrated) corresponding to the second active layer 412 and the second laser light may be arranged under the second optical output 418.

The bottom ohmic contact 420 may be arranged on a backside of the substrate layer 402. The top ohmic contact 422 may be arranged on the third DBR 414. The middle ohmic contact 424 may be arranged on the second DBR. For example, the middle ohmic contact 424 may be arranged on the contact buffer 410. The contact buffer 410 may be an ohmic contact layer and/or an electrically conductive contact layer that is arranged on the second DBR. For example, the contact buffer 410 may extend laterally across the VCSEL structure 400. In some implementations, the contact buffer may be made of an n-type material in order to enhance a current injection efficiency and/or current addressing convenience. The contact buffer 410 may include a first portion that is arranged between the second DBR 408 and the middle ohmic contact 424, with the first portion of the contact buffer 410 being in electrical contact with the middle ohmic contact 424. The contact buffer 410 may further include a second portion that is arranged between the second DBR 408 between and third DBR 414.

The bottom ohmic contact 420 and the middle ohmic contact 424 may be configured to cause a first electric current to flow between the bottom ohmic contact 420 and the middle ohmic contact 424 for producing the first laser light at the first active layer 406. For example, a voltage may be applied across the bottom ohmic contact 420 and the middle ohmic contact 424 to generate the first electric current.

The middle ohmic contact 424 and the top ohmic contact 422 may be configured to cause a second electric current to flow between the contact buffer 410 and the top ohmic contact 422 for producing the second laser light at the second active layer 412. For example, a voltage may be applied across the middle ohmic contact 424 and the top ohmic contact 422 to generate the second electric current. Since the contact buffer 410 is in electrical contact with the middle ohmic contact 424, a supply potential applied to the middle ohmic contact 424 it conducted by the contact buffer 410. If a supply potential is also applied to the top ohmic contact 422, the second electric current may be generated. As a result, the first electric current and the second electric current may be configured to be driven independently. For example, a first driver may be used to drive the first electric current and a second driver may be used to drive the second electric current. Thus, the first laser light and the second laser light may be driven independently by the first driver and the second driver, respectively.

The VCSEL structure 400 may optionally include the fourth DBR 426 arranged between the first active layer 406 and the second DBR 408. The fourth DBR 426 may be configured with a fourth photonic stopband having a fourth frequency bandwidth. In addition, the fourth DBR 426 may include a fourth plurality of alternately stacked high-index layers and low-index layers, where each high-index layer and each low-index layer of the fourth plurality of alternately stacked high-index layers and low-index layers has a respective fourth optical thickness based on the first wavelength λ1. In some implementations, the fourth DBR 426 may be part of the first DBR 404. In some implementations, the fourth DBR 426 may be based on a fourth wavelength 24 that has a value between the first wavelength λ1 and the second wavelength λ2. The fourth DBR 426 may be included to provide improved performance in generating the first laser light.

The VCSEL structure 400 may optionally include the fifth DBR 428 arranged between the second DBR 408 and the second active layer 412. The fifth DBR 428 may be configured with a fifth stopband having a fifth frequency bandwidth. In addition, the fifth DBR 428 may include a fifth plurality of alternately stacked high-index layers and low-index layers, where each high-index layer and each low-index layer of the fifth plurality of alternately stacked high-index layers and low-index layers has a respective fifth optical thickness based on the third wavelength λ3. In some implementations, the fifth DBR 428 may be part of the third DBR 414. In some implementations, the fifth DBR 428 may be based on a fifth wavelength 25 that has a value between the second wavelength λ2 and the third wavelength λ3. The fifth DBR 428 may be included to provide improved performance in generating the second laser light.

For wavelength values corresponding to the first DBR 404 and the third DBR 414, the first wavelength λ1 may be greater than, less than, or equal to the third wavelength λ3.

The VCSEL structure 400 includes two active regions focusing on two different wavelength bands and at least three reflector mirrors (e.g., at least three DBRs). Thus, a single

VCSEL chip with compact epitaxial structure can be obtained to provide lasing at multiple wavelength bands.

A current confinement aperture in the VCSEL structure 400 can be obtained by different approaches such as mesa, trench, oxidation, implantation, or the combination of these approaches. Also, each active region can also have a multi-junction scheme.

The VCSEL structure 400 can be used to obtain compact VCSEL arrays emitting at two different wavelength bands in a single chip to save cost for 3D sensing (3DS) or datacom applications.

As indicated above, FIG. 4 is provided as an example. Other examples may differ from what is described with regard to FIG. 4.

FIG. 5 is a diagram depicting a cross-section of a VCSEL structure 500 according to one or more implementations. The VCSEL structure 500 may be similar to the VCSEL structure 400 described in connection with FIG. 4, with the exception that the VCSEL structure 500 includes a tunnel-junction layer 502 and an optional sixth DBR 504. Thus, the VCSEL structure 500 may be part of a chip-level integrated dual-emission-wavelength emitter (e.g., a dual-emission-wavelength VCSEL device) integrated on a single laser chip. The VCSEL structure 500 is configured with two separate wavelength regimes (e.g., dual-emission-wavelength regimes). In other words, the VCSEL structure 500 may be configured to generate laser beams at two different emission wavelengths.

The tunnel-junction layer 502 may be arranged in the first DBR 404, in the second DBR 408, or in the third DBR 414. In this example, the tunnel-junction layer 502 is arranged in the first DBR 404. The tunnel-junction layer 502 may be used to change a polarity so as to make an n-type contact buffer under the middle ohmic contact 424. For example, when considering an epitaxy growth of gallium arsenide (GaAs) or indium phosphide (InP)-based devices typically use n-type substrates for the substrate layer, the tunnel-junction layer 502 can be inserted into one of the DBRs 404, 408, or 414 to change a polarity so as to make an n-type contact buffer under the middle ohmic contact 424.

The sixth DBR 504 may be a dielectric DBR or a semiconductor DBR arranged on the second DBR 408 at the first optical output 416. For example, the sixth DBR 504 may be arranged on the contact buffer 410 and at least partially surrounded by the middle ohmic contact 424. The sixth DBR 504 may be configured with a sixth photonic stopband having a sixth frequency bandwidth. The sixth DBR 504 may include sixth plurality of alternately stacked high-index layers and low-index layers, where each high-index layer and each low-index layer of the sixth plurality of alternately stacked high-index layers and low-index layers has a respective sixth optical thickness based on the first wavelength λ1. The sixth DBR 504 may be included to provide improved performance in an emission of the first laser light.

As indicated above, FIG. 5 is provided as an example. Other examples may differ from what is described with regard to FIG. 5.

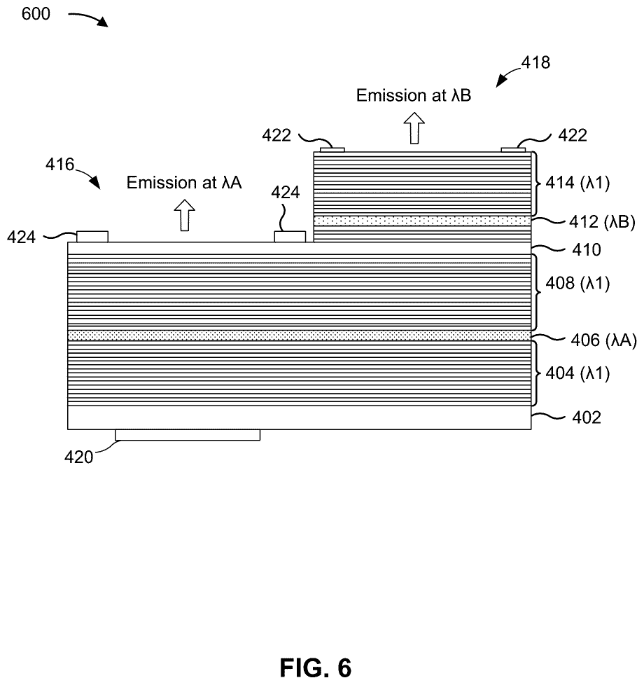

FIG. 6 is a diagram depicting a cross-section of a VCSEL structure 600 according to one or more implementations. The VCSEL structure 600 may be similar to the VCSEL structure 400 described in connection with FIG. 4, with the exception that the first DBR 404, the second DBR 408, and the third DBR 414 are all based on a same wavelength (e.g., a same reflection wavelength), such as the first wavelength λ1.

Thus, the first DBR 404 may include a first plurality of alternately stacked high-index layers and low-index layers, where each high-index layer and each low-index layer of the first plurality of alternately stacked high-index layers and low-index layers has a respective first optical thickness based on a reflection wavelength. The second DBR 408 may include a second plurality of alternately stacked high-index layers and low-index layers, where each high-index layer and each low-index layer of the second plurality of alternately stacked high-index layers and low-index layers has a respective second optical thickness based on the reflection wavelength. The third DBR 414 may include a third plurality of alternately stacked high-index layers and low-index layers, where each high-index layer and each low-index layer of the third plurality of alternately stacked high-index layers and low-index layers has a respective third optical thickness based on the reflection wavelength. In some implementations, the reflection wavelength may be equal to the first emission wavelength λA, may be equal to the second emission wavelength λB, or may be equal to a value between the first emission wavelength λA and the second emission wavelength λB. For example, the reflection wavelength may be equal to an average of the first emission wavelength λA and the second emission wavelength λB.

The VCSEL structure 600 may include any of the optional components described above, including the fourth DBR 426, the fifth DBR 428, the sixth DBR 504, and/or the tunnel-junction layer 502.

Dual wavelengths of the VCSEL structure 600 can be achieved by the first DBR 404, the second DBR 408, and the third DBR 414 that are based on the same wavelength and which may exhibit multiple stopbands. For example, a grating-based DBR may have multiple stop-bands. Thus, each grating-based DBR can provide high reflectivity at multiple wavelength bands. The multiple stop-bands at different wavelengths can also be leveraged to obtain a compact VCSEL epitaxial structure that can emit light at different stopbands from a same epitaxial structure. The first emission wavelength λA and the second emission wavelength λB may be placed at different stopbands. For example, a difference between the first emission wavelength λA and the second emission wavelength λB may be above 100 nm in a wavelength range of 1 micron. In other words, the first emission wavelength λA may be is provided in a first order stopband (e.g., a fundamental order stopband), and the second emission wavelength λB may be provided in a higher order stopband (e.g., a second order stopband, a third order stopband, a fourth order stopband, etc.) that is different from the first order stopband.

As indicated above, FIG. 6 is provided as an example. Other examples may differ from what is described with regard to FIG. 6.

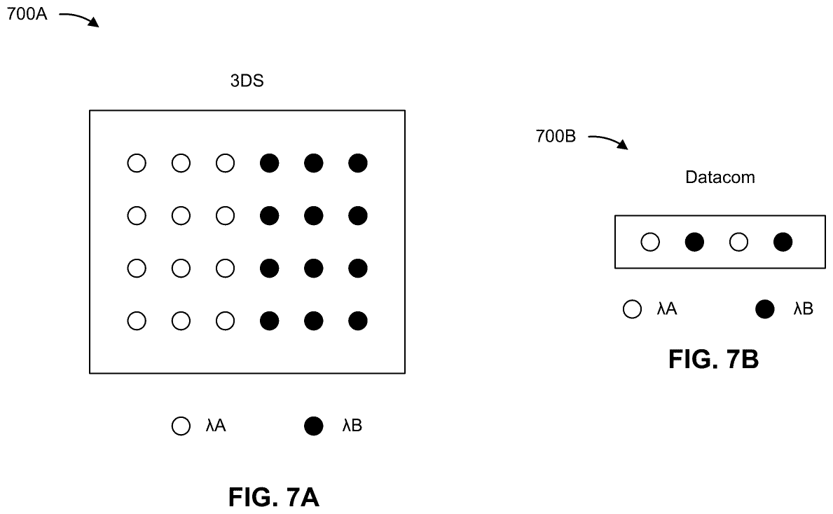

FIG. 7A shows a VCSEL chip 700A configured for dual-wavelength band emission according to one or more implementations. For example, the VCSEL chip 700A may be a dual-emission-wavelength VCSEL device configured for 3DS applications, such as LiDAR. The dual-emission-wavelength emitters described herein can be used to obtain compact VCSEL arrays emitting at two different wavelength bands in a single chip to save manufacturing cost and to reduce power consumption. Each dot represents a VCSEL emitter (e.g., an emission structure) within a single VCSEL chip (e.g., a single VCSEL structure). The VCSEL emitters may be formed in a single emitter structure, such as the VCSEL structures 400, 500, and 600 shown in FIGS. 4-6. A first subset of VCSEL emitters, represented by a first group of dots, may be configured to lase at the first emission wavelength λA, while a second subset of VCSEL emitters, represented by a second group of dots, may be configured to lase at the second emission wavelength λB.

The VCSEL chip 700A can provide emitters lasing at different wavelengths from a same epi with reflector mirrors, as described above in conjunction with FIGS. 4-6, to reduce module size and cost. Each VCSEL structure includes two active regions focusing on two different wavelength bands and at least three reflector mirrors (e.g., at least three DBRs). Thus, a single VCSEL chip with compact epitaxial structure can be obtained to provide lasing at multiple wavelength bands.

As indicated above, FIG. 7A is provided as an example. Other examples may differ from what is described with regard to FIG. 7A.

FIG. 7B shows a VCSEL chip 700B configured for dual-wavelength band emission according to one or more implementations. For example, the VCSEL chip may be a dual-emission-wavelength VCSEL device configured for data communication (datacom) applications. The dual-emission-wavelength emitters described herein can be used to obtain compact VCSEL arrays emitting at two different wavelength bands in a single chip to save manufacturing cost and to reduce power consumption. Each dot represents a VCSEL emitter (e.g., an emission structure) within a single VCSEL chip (e.g., a single VCSEL structure). The VCSEL emitters may be formed in a single emitter structure, such as the VCSEL structures 400, 500, and 600 shown in FIGS. 4-6. A first subset of VCSEL emitters, represented by a first group of dots, may be configured to lase at the first emission wavelength λA, while a second subset of VCSEL emitters, represented by a second group of dots, may be configured to lase at the second emission wavelength λB.

The VCSEL chip 700B can provide emitters lasing at different wavelengths from a same epi with reflector mirrors, as described above in conjunction with FIGS. 4-6, to save module size and cost. Each VCSEL structure includes two active regions focusing on two different wavelength bands and at least three reflector mirrors (e.g., at least three DBRs). Thus, a single VCSEL chip with compact epitaxial structure can be obtained to provide lasing at multiple wavelength bands.

As indicated above, FIG. 7B is provided as an example. Other examples may differ from what is described with regard to FIG. 7B.

One or more implementations described herein may be applicable to various architectures of a VCSEL, such as oxide confined VCSEL, implant-only VCSEL, and mesa type devices. Moreover, one or more implementations described herein may be applicable across several wavelengths (e.g., 800 nm to 2000 nm) and across different material systems (e.g., GaAs substrates and InP substrates). Moreover, a VCSEL structure may be a top-emitting VCSEL structure or a bottom-emitting VCSEL structure. Moreover, emitter numbers, sizes, and array shapes can vary depending on the application. Moreover, each VCSEL structure may have an oxidation aperture with any suitable aperture shape.

Each VCSEL structure includes two active regions focusing on two different wavelength bands and three reflector mirrors. The middle mirror (e.g., the middle DBR) shared by the two emission structures of the VCSEL structure provides high reflectivity at two different wavelength bands at a same time. Accordingly, each VCSEL structure may be configured to provide lasing at multiple wavelength bands. In addition, a single VCSEL chip with a compact epitaxial structure can be obtained to provide lasing at multiple wavelength bands simultaneously, which can save the module size and cost.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). The terms “high-index” and “low-index” are only meant to be relative to each other and not restricted to any specific range of absolute index-of-refraction. Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical-cavity surface-emitting laser (VCSEL) device, comprising:
a substrate layer;
a first distributed Bragg reflector (DBR) arranged on the substrate layer, wherein the first DBR is configured with a first photonic stopband having a first frequency bandwidth, wherein the first DBR comprises a first plurality of alternately stacked high-index layers and low-index layers, and wherein each high-index layer and each low-index layer of the first plurality of alternately stacked high-index layers and low-index layers has a respective first optical thickness based on a first wavelength;
a second DBR arranged on the first DBR, wherein the second DBR is configured with a second photonic stopband having a second frequency bandwidth that partially, but not fully, overlaps with the first frequency bandwidth, wherein the second DBR comprises a second plurality of alternately stacked high-index layers and low-index layers, and wherein each high-index layer and each low-index layer of the second plurality of alternately stacked high-index layers and low-index layers has a respective second optical thickness based on a second wavelength that is different from the first wavelength;
an active layer comprising one or more quantum wells and configured to generate a laser light at an emission wavelength, wherein the active layer is arranged between the first DBR and the second DBR; and
an optical output arranged over the second DBR, wherein the laser light is emitted from the VCSEL device via the optical output.

2. The VCSEL device of claim 1, further comprising:
a bottom electrical contact arranged on a backside of the substrate layer; and
a top electrical contact arranged on the second DBR,
wherein the bottom electrical contact and the top electrical contact are configured to cause an electric current to flow between the bottom electrical contact and the top electrical contact for producing the laser light at the active layer.

3. The VCSEL device of claim 1, wherein the active layer has a gain profile and a layer thickness configured for emitting the laser light at the emission wavelength.

4. The VCSEL device of claim 1, wherein the first photonic stopband has a first center frequency, and
wherein the second photonic stopband has a second center frequency offset from the first center frequency.

5. A dual-emission-wavelength vertical-cavity surface-emitting laser (VCSEL) device, comprising:
a substrate layer;
a first distributed Bragg reflector (DBR) arranged on the substrate layer, wherein the first DBR is configured with a first photonic stopband having a first frequency bandwidth, wherein the first DBR comprises a first plurality of alternately stacked high-index layers and low-index layers, and wherein each high-index layer and each low-index layer of the first plurality of alternately stacked high-index layers and low-index layers has a respective first optical thickness based on a first wavelength;
a second DBR arranged on the first DBR, wherein the second DBR is configured with a second photonic stopband having a second frequency bandwidth that partially, but not fully, overlaps with the first frequency bandwidth, wherein the second DBR comprises a second plurality of alternately stacked high-index layers and low-index layers, and wherein each high-index layer and each low-index layer of the second plurality of alternately stacked high-index layers and low-index layers has a respective second optical thickness based on a second wavelength that is different from the first wavelength;
a third DBR arranged on the second DBR, wherein the third DBR is configured with a third photonic stopband having a third frequency bandwidth that partially, but not fully, overlaps with the first frequency bandwidth and the second frequency bandwidth, wherein the third DBR comprises a third plurality of alternately stacked high-index layers and low-index layers, and wherein each high-index layer and each low-index layer of the third plurality of alternately stacked high-index layers and low-index layers has a respective third optical thickness based on a third wavelength that is different from the first wavelength and the second wavelength,
a first active layer comprising one or more first quantum wells and configured to generate a first laser light at a first emission wavelength, wherein the first active layer is arranged between the first DBR and the second DBR;
a second active layer comprising one or more second quantum wells and configured to generate a second laser light at a second emission wavelength that is different from the first emission wavelength, wherein the second active layer is arranged between the second DBR and the third DBR;
a first optical output arranged over the second DBR, wherein the first laser light is emitted from the dual-emission-wavelength VCSEL device via the first optical output; and
a second optical output arranged over the third DBR, wherein the second laser light is emitted from the dual-emission-wavelength VCSEL device via the second optical output.

6. The dual-emission-wavelength VCSEL device of claim 5, wherein the second wavelength is between the first wavelength and the third wavelength.

7. The dual-emission-wavelength VCSEL device of claim 5, further comprising:
a bottom electrical contact arranged on a backside of the substrate layer;
a top electrical contact arranged on the third DBR;
a middle electrical contact arranged on the second DBR; and
a contact buffer arranged on the second DBR, wherein a first portion of the contact buffer is arranged between the second DBR and the middle electrical contact, wherein the contact buffer is in electrical contact with the middle electrical contact, and wherein a second portion of the contact buffer is arranged between the second DBR between and third DBR,
wherein the bottom electrical contact and the middle electrical contact are configured to cause a first electric current to flow between the bottom electrical contact and the middle electrical contact for producing the first laser light at the first active layer, and
wherein the middle electrical contact and the top electrical contact are configured to cause a second electric current to flow between the contact buffer and the top electrical contact for producing the second laser light at the second active layer.

8. The dual-emission-wavelength VCSEL device of claim 7, wherein the contact buffer is made of an n-type material.

9. The dual-emission-wavelength VCSEL device of claim 7, wherein the first electric current and the second electric current are configured to be driven independently.

10. The dual-emission-wavelength VCSEL device of claim 5, wherein the first active layer has a first gain profile and a first thickness configured for emitting the first laser light at the first emission wavelength, and
wherein the second active layer has a second gain profile and a second thickness configured for emitting the second laser light at the second emission wavelength.

11. The dual-emission-wavelength VCSEL device of claim 5, wherein the first photonic stopband has a first center frequency,
wherein the second photonic stopband has a second center frequency offset from the first center frequency, and
wherein the third photonic stopband has a third center frequency offset from the first center frequency and the second center frequency.

12. The dual-emission-wavelength VCSEL device of claim 5, wherein the second wavelength is between the first wavelength and the third wavelength, and wherein the second wavelength is equal to an average of the first wavelength and the third wavelength.

13. The dual-emission-wavelength VCSEL device of claim 5, wherein the dual-emission-wavelength VCSEL device is a single laser chip.

14. The dual-emission-wavelength VCSEL device of claim 5, further comprising:
a tunnel-junction layer, wherein the tunnel-junction layer is arranged in the first DBR, in the second DBR, or in the third DBR.

15. The dual-emission-wavelength VCSEL device of claim 5, further comprising:
a fourth DBR arranged between the first active layer and the second DBR, wherein the fourth DBR is configured with a fourth photonic stopband having a fourth frequency bandwidth, wherein the fourth DBR comprises a fourth plurality of alternately stacked high-index layers and low-index layers, and wherein each high-index layer and each low-index layer of the fourth plurality of alternately stacked high-index layers and low-index layers has a respective fourth optical thickness based on the first wavelength.

16. The dual-emission-wavelength VCSEL device of claim 5, further comprising:
a fourth DBR arranged between the second DBR and the second active layer, wherein the fourth DBR is configured with a fourth photonic stopband having a fourth frequency bandwidth, wherein the fourth DBR comprises a fourth plurality of alternately stacked high-index layers and low-index layers, and wherein each high-index layer and each low-index layer of the fourth plurality of alternately stacked high-index layers and low-index layers has a respective fourth optical thickness based on the third wavelength.

17. The dual-emission-wavelength VCSEL device of claim 5, further comprising:
a fourth DBR arranged on the second DBR at the first optical output, wherein the fourth DBR is configured with a fourth photonic stopband having a fourth frequency bandwidth, wherein the fourth DBR comprises a fourth plurality of alternately stacked high-index layers and low-index layers, and wherein each high-index layer and each low-index layer of the fourth plurality of alternately stacked high-index layers and low-index layers has a respective fourth optical thickness based on the first wavelength.

18. The dual-emission-wavelength VCSEL device of claim 17, wherein the fourth DBR comprises at least one of a dielectric DBR or a semiconductor DBR.

19. The dual-emission-wavelength VCSEL device of claim 5, wherein the third DBR is a dielectric DBR or includes a dielectric DBR.

20. A dual-emission-wavelength vertical-cavity surface-emitting laser (VCSEL) device, comprising:
a substrate layer;
a first distributed Bragg reflector (DBR) arranged on the substrate layer, wherein the first DBR comprises a first plurality of alternately stacked high-index layers and low-index layers, and wherein each high-index layer and each low-index layer of the first plurality of alternately stacked high-index layers and low-index layers has a respective first optical thickness based on a reflection wavelength;
a second DBR arranged on the first DBR, wherein the second DBR comprises a second plurality of alternately stacked high-index layers and low-index layers, and wherein each high-index layer and each low-index layer of the second plurality of alternately stacked high-index layers and low-index layers has a respective second optical thickness based on the reflection wavelength;
a third DBR arranged on the second DBR, wherein the third DBR comprises a third plurality of alternately stacked high-index layers and low-index layers, and wherein each high-index layer and each low-index layer of the third plurality of alternately stacked high-index layers and low-index layers has a respective third optical thickness based on the reflection wavelength;
a first active layer comprising one or more first quantum wells and configured to generate a first laser light at a first emission wavelength, wherein the first active layer is arranged between the first DBR and the second DBR;
a second active layer comprising one or more second quantum wells and configured to generate a second laser light at a second emission wavelength that is different from the first emission wavelength, wherein the second active layer is arranged between the second DBR and the third DBR;
a first optical output arranged over the second DBR, wherein the first laser light is emitted from the dual-emission-wavelength VCSEL device via the first optical output; and
a second optical output arranged over the third DBR, wherein the second laser light is emitted from the dual-emission-wavelength VCSEL device via the second optical output.

21. The dual-emission-wavelength VCSEL device of claim 20, further comprising:
a bottom electrical contact arranged on a backside of the substrate layer;
a top electrical contact arranged on the third DBR;
a middle electrical contact arranged on the second DBR; and
a contact buffer arranged on the second DBR, wherein a first portion of the contact buffer is arranged between the second DBR between and the middle electrical contact, wherein the contact buffer is in electrical contact with the middle electrical contact, and wherein a second portion of the contact buffer is arranged between the second DBR between and third DBR,
wherein the bottom electrical contact and the middle electrical contact are configured to cause a first electric current to flow between the bottom electrical contact and the middle electrical contact for producing the first laser light at the first active layer, and
wherein the middle electrical contact and the top electrical contact are configured to cause a second electric current to flow between the contact buffer and the top electrical contact for producing the second laser light at the second active layer.

22. The dual-emission-wavelength VCSEL device of claim λ1, wherein the contact buffer is made of an n-type material.

23. The dual-emission-wavelength VCSEL device of claim 20, wherein the first active layer has a first gain profile and a first layer thickness configured for emitting the first laser light at the first emission wavelength, and
wherein the second active layer has a second gain profile configured for emitting the second laser light at the second emission wavelength.

24. The dual-emission-wavelength VCSEL device of claim 20, wherein the reflection wavelength is equal to an average of the first emission wavelength and the second emission wavelength.

25. The dual-emission-wavelength VCSEL device of claim 20, wherein the dual-emission-wavelength VCSEL device is a single laser chip.

26. The dual-emission-wavelength VCSEL device of claim 20, further comprising:
a tunnel-junction layer, wherein the tunnel-junction layer is arranged in the first DBR, in the second DBR, or in the third DBR.

27. The dual-emission-wavelength VCSEL device of claim 20, wherein the first emission wavelength is provided in a first order stopband, and
wherein the second emission wavelength is provided in a higher order stopband.
